(19) United States
(12) Patent Application Publication
(10) Pub. No.: US 2014/0313452 A1
(43) Pub. Date: Oct. 23, 2014

(54) Glass Assembly on Monitor Array

(71) Applicant: MANUFACTURING RESOURCES INTERNATIONAL, INC., Alpharetta, GA (US)

(72) Inventors: William Dunn, Alpharetta, GA (US); Michael LeCave, Gainesville, GA (US); Martin Jarl, Alpharetta, GA (US)

(73) Assignee: MANUFACTURING RESOURCES INTERNATIONAL, INC., Alpharetta, GA (US)

(21) Appl. No.: 14/192,435

(22) Filed: Feb. 27, 2014

Related U.S. Application Data
(60) Provisional application No. 61/786,984, filed on Mar. 15, 2013.

(51) Int. Cl. H05K 5/00; G02F 1/1333; G02B 1/11

(52) U.S. Cl. CPC H05K 5/0017; G02B 1/11; G02F 1/133308; G02F 2001/133331
USPC 349/58; 359/601; 361/679.01; 428/161; 428/76; 428/166; 156/106

(57) ABSTRACT

Exemplary embodiments disclosed herein provide a glass assembly having a bottom sheet of glass which is substantially planar, bonded to a top sheet of glass which is substantially concave. A layer of adhesive is preferably interposed between the bottom and top sheets of glass. In an exemplary embodiment, the amount of adhesive used would be less than the amount required to hold both sheets of glass in a parallel planar arrangement. The layer of adhesive may be contained between the two sheets of glass by a perimeter of adhesive tape, also interposed between the top and bottom sheets of glass. The assembly can be used with an electronic display where the display is positioned adjacent to the top sheet of glass, and due to its concavity, the electronic display can bow towards the top sheet of glass without actually contacting the glass.

### CROSS-REFERENCE TO RELATED APPLICATIONS

This application claims priority to U.S. Provisional Application No. 61/786,984, filed on Mar. 15, 2013 and herein incorporated by reference in its entirety.

### TECHNICAL FIELD

Embodiments generally relate to electronic display assemblies.

### BACKGROUND

Electronic display assemblies are known to be very thin and over time these displays can warp outwardly, towards a transparent protective plate or glass assembly. If the display contacts the protective plate, it can produce visual anomalies in the image and may even wet bond the display surface to the protective plate.

### SUMMARY OF THE EXEMPLARY EMBODIMENTS OF THE INVENTION

Exemplary embodiments disclosed herein provide a glass assembly having a bottom sheet of glass which is substantially planar, bonded to a top sheet of glass which is substantially concave. A layer of adhesive is preferably interposed between the bottom and top sheets of glass. In an exemplary embodiment, the amount of adhesive used would be less than the amount required to hold both sheets of glass in a parallel planar arrangement. The layer of adhesive may be contained between the two sheets of glass by a perimeter of adhesive tape, also interposed between the top and bottom sheets of glass. The assembly can be used with an electronic display where the display is positioned adjacent to the top sheet of glass, and due to its concavity, the electronic display can bow towards the top sheet of glass without actually contacting the glass.

Exemplary embodiments disclosed herein provide a glass assembly having a bottom sheet of glass which is substantially planar, bonded to a top sheet of glass which is substantially concave. A layer of adhesive is preferably interposed between the bottom and top sheets of glass. In an exemplary embodiment, the amount of adhesive used would be less than the amount required to hold both sheets of glass in a parallel planar arrangement. The layer of adhesive may be contained between the two sheets of glass by a perimeter of adhesive tape, also interposed between the top and bottom sheets of glass. The assembly can be used with an electronic display where the display is positioned adjacent to the top sheet of glass, and due to its concavity, the electronic display can bow towards the top sheet of glass without actually contacting the glass.

### BRIEF DESCRIPTION OF THE DRAWINGS

A better understanding of an exemplary embodiment will be obtained from a reading of the following detailed description and the accompanying drawings wherein identical reference characters refer to identical parts and in which:

FIG. 1 is a front perspective view of an array of electronic displays.

FIG. 2 is a front perspective view of an electronic display assembly, showing the section line 3-3.

FIG. 3 is a perspective section view of the electronic display assembly and showing detail 4.

FIG. 4 is a perspective section view of detail 4, shown in FIG. 3.

FIG. 5 is a planar section view of a typical electronic display used with a typical front glass assembly.

FIG. 6 shows an exemplary front glass assembly and the section line 7-7.

FIG. 7 shows a cross-sectional view from the 7-7 cross-section shown in FIG. 6.

FIG. 8 is a side view of the detail circle in FIG. 7, which was a cross section through section 7-7 of FIG. 6.

FIG. 9 shows the view of the detailed circle from FIG. 6 where the front glass has been removed.

FIG. 10 shows a sectional view of the glass assembly after exiting the curing process (typically a UV oven) when performing a traditional bonding process.

FIG. 11 shows a sectional view of the glass assembly after exiting the curing process when using the special bonding method described here.

### DETAILED DESCRIPTION

The invention is described more fully hereinafter with reference to the accompanying drawings, in which exemplary embodiments of the invention are shown. This invention may, however, be embodied in many different forms and should not be construed as limited to the exemplary embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

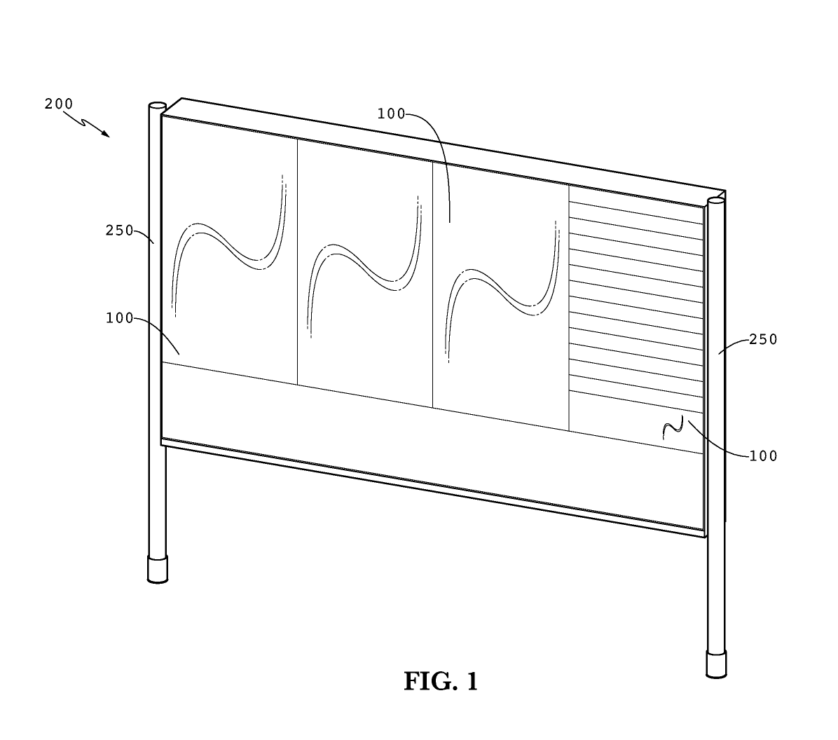

FIG. 1 is a front perspective view of an array of electronic displays 200. A plurality of electronic display assemblies 100 are mounted to a frame 250.

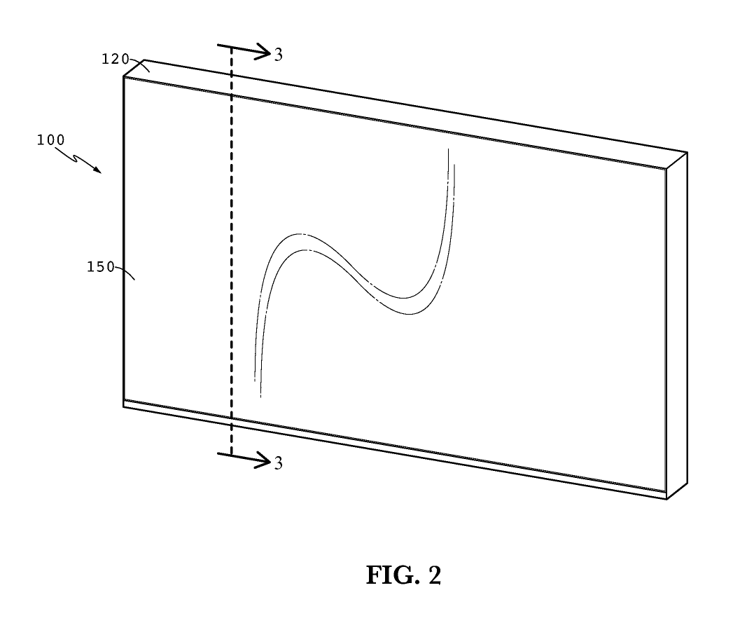

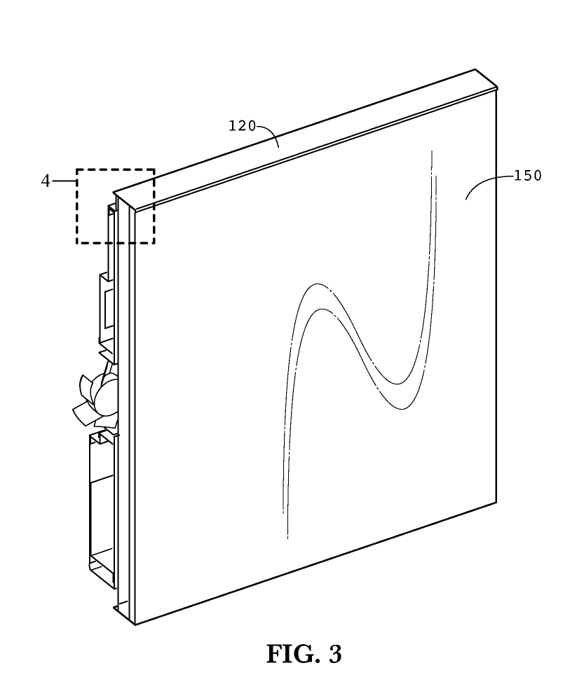

FIG. 2 is a front perspective view of an electronic display assembly 100, showing the section line 3-3. Each electronic display assembly 100 preferably contains a frame 120 which holds a protective front glass assembly 150. FIG. 3 is a perspective section view of the electronic display assembly and showing detail 4.

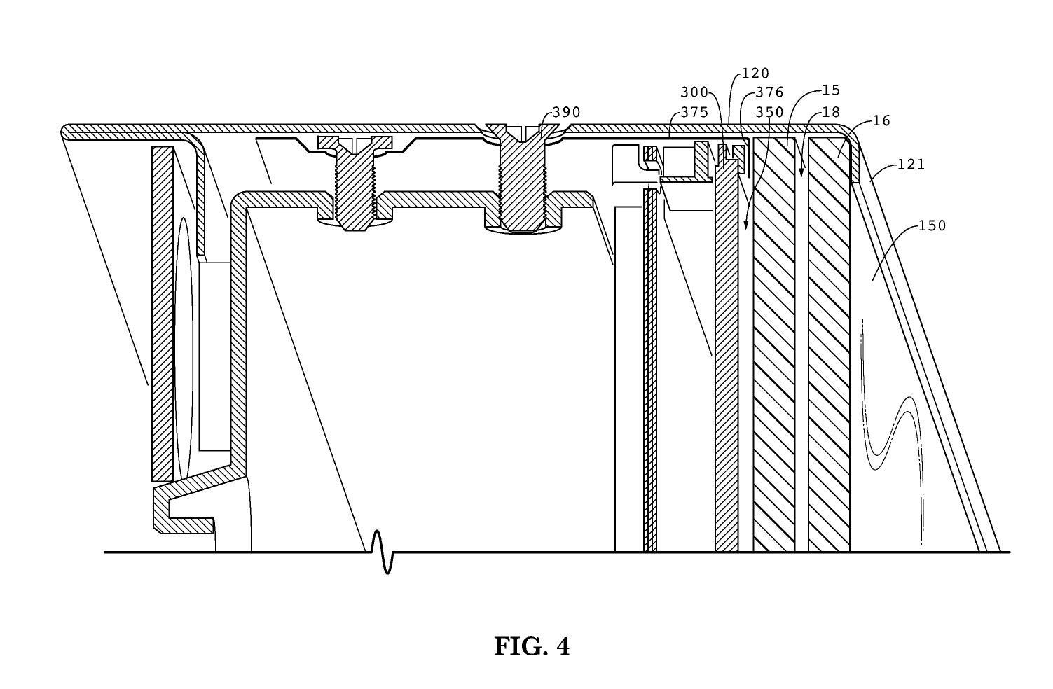

FIG. 4 is a perspective section view of detail 4, shown in FIG. 3. A display subassembly 375 preferably contains the electronic display 300, which could be any one of the following: LCD, plasma, OLED, light emitting polymer (LEP), and organic electro luminescence (OEL). In the embodiment shown here, the electronic display 300 is an LED direct backlight LCD. The display subassembly 375 is secured to the frame 120, and this could be done with an adhesive of some type and can be reinforced with a fastener 390.

The display subassembly 375 preferably contains a ledge 376 which runs around the perimeter of the display 300. The front glass assembly 150 is preferably sandwiched in between the ledge 376 and a corresponding ledge 121 on the frame 120, which should be sized as small as possible so that each display assembly 100 could be mounted as close as possible to one another, giving the appearance of a large seamless display. In some embodiments, the front glass assembly 16 is a single piece of glass. However, in an exemplary embodiment the front glass assembly comprises a front sheet of glass 16 which is laminated to a rear sheet of glass 15 with a layer of adhesive 18, preferably an optical adhesive.

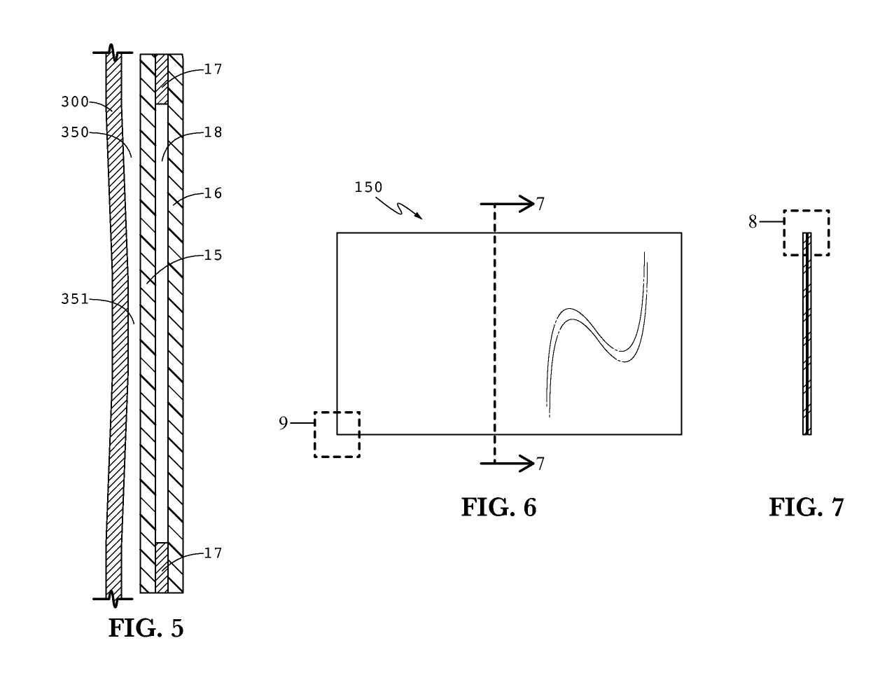

There is preferably a small gap 350 defined between the rear surface of the glass assembly 150 and the front surface of the electronic display 300. It has been found that in some applications the electronic display 300 is a relatively thin and flexible, and over time can sag or bow outward. This phenomenon is illustrated in FIG. 5. As can be observed, the electronic display 300 is bowing outwards towards the rear sheet of glass 15, reducing the gap 350 to a minimum point 351. In some cases the gap 350 at the minimum point 351 may go to zero, where the front surface of the electronic assembly 300 may wet bond to the rear sheet of glass 15. To account for this phenomenon, the inventors have discovered a modification to the glass assembly process, which will now be discussed.

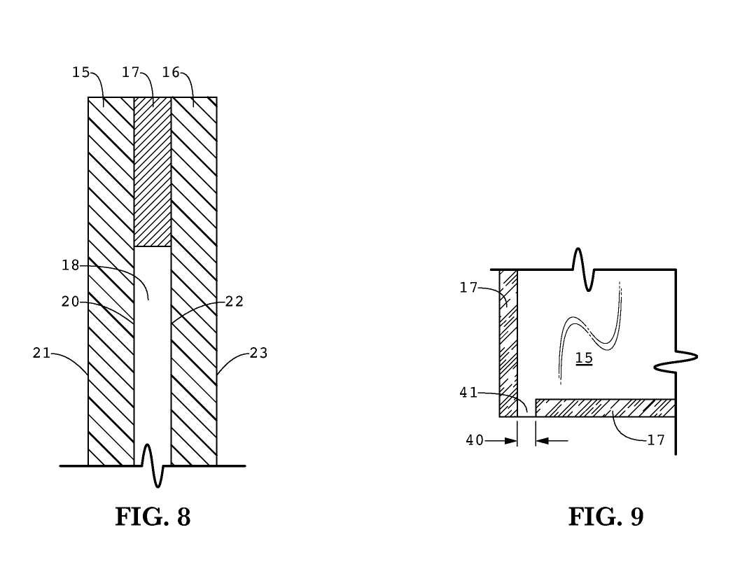

FIG. 6 shows an exemplary front glass assembly 150, which is comprised of several different layers. The cross-section line 7-7 is shown passing through the center of the front glass assembly 150. FIG. 7 shows a cross-sectional view from the 7-7 cross-section shown in FIG. 6. Due to the scale of the figure it is difficult to discern the individual layers of the front glass assembly 150. Thus, FIG. 7 contains the details circle which illustrates the detailed view shown in FIG. 8.

FIG. 8 is a side view of the detail circle in FIG. 7, which was a cross section through section 7-7 of FIG. 6. The various layers of an exemplary embodiment are shown. In an exemplary embodiment, both glass 15 and 16 are preferably anti-reflective (AR) glass. Some embodiments may have one surface of the glass coated with an AR coating. Exemplary embodiments may have a pyrolytic surface as the AR coating. Further, embodiments may have a pyrolytic surface as the outer surface of the panel. Referring to FIG. 8, an exemplary embodiment would contain a pyrolytic surface on outer surfaces 23 and 21, where the opposite surfaces 20 and 22 are in contact with the adhesive 18.

An exemplary anti-reflective glass could be Pilkington OptiView™ glass which is commercially available from Pilkington Building and Specialty Glass Products of Toledo, Ohio (herein ‘OptiView glass’). www.pilkington.com The document “Pilkington OptiView™ Anti-Reflective Glass,” Form No. 4483, is herein incorporated by reference in its entirety.

It should be noted, that any glass which meets the performance characteristics set by the OptiView glass would fall within the exemplary embodiments. OptiView glass was simply selected for exemplary purposes. Chart 1 provides typical performance characteristics for two pieces of glass, each with an anti-reflective pyrolytic coating on one side, where the two pieces of glass are laminated or bonded together. Currently, Pilkington Glass does not provide this dual-layered glass with two pyrolytic coatings. Users must purchase single pieces of glass with a single pyrolytic coating and laminate or bond the pieces themselves. See the Chart 1 Notes for specifics.

CHART 1

| | Visible Light | | | Total Solar Energy | | | | | | Solar | |
|---|---|---|---|---|---|---|---|---|---|---|---|
| Nominal | Trans- | Reflec- | Reflec- | Trans- | Reflect- | UV | U-Factor | | | Heat | |
| Glass | mittance | tance | tance | mittance | ance | Trans- | U.S. | U.S. | | Gain | Shading |
| Thickness | % | % Outside | % Inside | % | % | mittance % | Summer* | Winter* | European** | Coefficient | Coefficient |
| ¼ in | 92 | 1.7 | 1.7 | 70 | 3 | <1 | 0.68 | 0.81 | 4.7 | 0.77 | 0.89 |
| ½ in | 89 | 1.6 | 1.6 | 63 | 3 | <1 | 0.65 | 0.77 | 4.5 | 0.72 | 0.83 |

Notes:
¼″ laminated glass: ⅛″ OptiView ™ (#1) + 0.030″ clear pvb with 99% UV absorptance + ⅛″ OptiView ™ (#4)
½″ laminated glass: ¼″ OptiView ™ (#1) + 0.030″ clear pvb with 99% UV absorptance + ¼″ OptiView ™ (#4)
*Btu/hr · sq ft · ° F.
**W/sq m · °K

Adhesive 18 is used to bond the glass layers 15 and 16. An optical adhesive is preferably used to bond the glass together. Even more preferably, an index-matched optical adhesive may be used. Exemplary embodiments may utilize Uvecol® S adhesive, commercially available from Cytec Surface Specialties, Inc. of Smyrna, Ga. www.cytec.com. The document “Uvecol® S UV Curable Glass Laminating System,” May 4, 2006, is herein incorporated by reference in its entirety. Embodiments may alternatively utilize Uvecol® A adhesive. In an exemplary embodiment, the glass layers 15 and 16 are laminated together by UV-curing the adhesive 18.

Very High Bond (VHB) tape 17 may be used to seal around the edges of the glass 15 and 16. In an exemplary embodiment, the VHB tape 17 would be a clear acrylic tape in a thickness between 0.5 mm and 3.0 mm.

An exemplary front glass assembly for small displays may utilize glass panels of thickness between 3.0-3.5 mm and VHB tape of thickness between 0.8-1.2 mm. An exemplary front glass assembly for larger displays may utilize glass panels of thickness between 6.0-6.5 mm and VHB tape of thickness between 1.0-1.5 mm.

FIG. 9 shows the view of the detailed circle from FIG. 6 where the front glass 16 has been removed. During an exemplary embodiment of the glass assembly process, the VHB tape 17 is applied to the perimeter of one sheet of glass, covering the entire perimeter of the glass sheet with the exception of a small gap 40. Once applied to the first sheet of glass, the second sheet is aligned with and applied to the other side of the VHB tape 17. Adhesive is then injected between the two glass sheets. The assembly is then angled so that air bubbles can escape out of the small gap 40 and sometimes excess adhesive 18. Once the air bubbles and any excess adhesive 18 have escaped, the gap 40 may be sealed with a second adhesive material 41. An exemplary second adhesive material 41 would be all temperature hot glue.

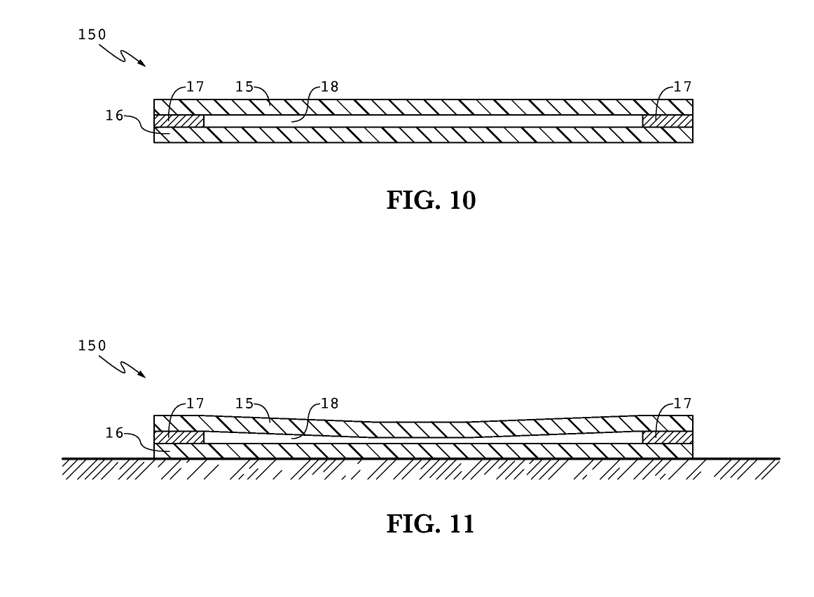

FIG. 10 shows a sectional view of the glass assembly 150 after exiting the curing process (typically a UV oven) when performing a traditional bonding process. In a traditional bonding process, the precise amount of adhesive 18 necessary to fill the space between the sheets 15 and 16 so that they remain parallel to one another after curing is determined (based on experiments and related calculations). This amount is then measured as the adhesive 18 is injected, so that the proper amount of adhesive is used to ensure that the sheets 15 and 16 remain substantially parallel after curing (as shown in FIG. 10).

However, in an exemplary embodiment of the special bonding method, a smaller amount of adhesive 18 is purposefully used so that during the curing process the rear sheet 15 will bow inwards towards the front sheet 16. FIG. 11 shows a sectional view of the glass assembly 150 after exiting the curing process when using the special bonding method described here. Preferably, the front sheet 16 is held flat while the rear sheet 15 is permitted to sag or bow downward. The front sheet 16 could be placed on a flat surface or a plurality of rollers; all that is required is for the front sheet 16 to remain substantially flat.

As can be observed, the rear sheet 15 has bowed inwards towards the front sheet 16, which now provides additional space for the electronic display 300 to bow forwards without contacting the rear surface of the rear sheet 15. The precise amount of bowing can be controlled based on the thickness of the VHB tape 17 and the reduction in the amount of adhesive 18 used. In some embodiments, the amount of bowing can be between 0.5 mm and 2 mm, but again this could be any amount that is desired. While it is preferable for the front sheet 16 to remain flat so that the resulting glass assembly 150, when viewed from the perspective of a viewer of the electronic display, the glass assembly 150 does not appear warped or cause any optical deficiencies as the front sheet 16 is flat, or substantially planar.

When oriented in this fashion (where the rear sheet 15 is on top and the front sheet 16 is on the bottom) it can be said that the rear sheet 15 transforms from a planar sheet to a concave sheet during the adhesive curing process. Alternatively, the cross-section, taken near the center of the resulting assembly as shown in FIG. 6, would indicate a resulting catenary produced by the rear sheet 15. Of course, it may not produce a mathematically perfect catenary, but the resulting cross-sectional shape could be described as substantially catenary. It should be noted that a catenary-like cross-section would also appear when you cut through the center of the resulting assembly, but perpendicular to the direction shown in FIG. 6. In other words, both cross-sections (vertical or horizontal) would produce catenary curves, but these curves would not typically be the same, specifically when the front glass assembly is not a perfect square.

Another way of describing the rear sheet from an exemplary embodiment would be to describe it as a three-dimensional catenary, produced by supporting only the perimeter of the rear sheet and allowing the center to bow due to (1) the natural weight of the sheet due to gravity and (2) forces due to the curing of the adhesive and the fact that the amount of adhesive used is preferably less than what would be required to produce a substantially planar rear sheet. In an exemplary embodiment, the amount of adhesive used may be reduced by 5%-25% when compared to the amount of adhesive required to produce a planar rear sheet with no excess adhesive wasted. The amount of adhesive could be measured by volume or weight.

Having shown and described a preferred embodiment of the invention, those skilled in the art will realize that many variations and modifications may be made to affect the described invention and still be within the scope of the claimed invention. Additionally, many of the elements indicated above may be altered or replaced by different elements which will provide the same result and fall within the spirit of the claimed invention. It is the intention, therefore, to limit the invention only as indicated by the scope of the claims.

We claim:

1. A glass assembly comprising:
a bottom sheet of glass which is substantially planar;
a top sheet of glass which is substantially concave; and
a layer of optical adhesive interposed between the top and bottom sheets of glass.

2. The glass assembly of claim 1 further comprising:
a layer of adhesive tape enclosing the optical adhesive between the top and bottom sheets of glass.

3. The glass assembly of claim 1 wherein:
the bottom and top sheets of glass contain anti-reflective layers.

4. The glass assembly of claim 1 wherein:
a cross-section taken near a center of the top sheet produces a catenary shape.

5. The glass assembly of claim 1 wherein:
the amount of adhesive placed between the top and bottom sheets is less than the amount of adhesive used to create a planar top sheet.

6. A glass assembly comprising:
a front sheet of glass which is substantially planar;
a rear sheet of glass which is a three dimensional catenary; and
a layer of optical adhesive interposed between the front and rear sheets of glass.

7. The glass assembly of claim 6 further comprising:
a layer of adhesive tape enclosing the optical adhesive between the top and bottom sheets of glass.

8. The glass assembly of claim 6 wherein:
the bottom and top sheets of glass contain anti-reflective layers.

9. A glass assembly comprising:
a bottom sheet of glass having a perimeter;
a layer of adhesive tape applied around the perimeter of the bottom sheet; and
a top sheet of glass placed atop the later of adhesive tape and having a center portion which bows towards the bottom sheet of glass.

10. The glass assembly of claim 9 further comprising:
a layer of optical adhesive interposed between the top and bottom sheets of glass.

11. The glass assembly of claim 9 further comprising:
a gap within the layer of adhesive tape which permits air bubbles to escape while the adhesive cures.

12. A method for assembling a first and second sheet of glass comprising the steps of:
applying adhesive tape to a perimeter of the first sheet of glass while leaving a gap where there is no adhesive tape;
placing the second sheet of glass atop the adhesive tape;
inserting optical adhesive into the gap;
holding the first sheet of glass such that it remains substantially planar; and
allowing the adhesive to cure which draws a center portion of the second sheet towards the first sheet.

13. The method of claim 12 further comprising the step of:
placing a second adhesive into the gap once the optical adhesive cures.

14. The method of claim 12 wherein:
the step of allowing the adhesive to cure causes the second sheet of glass to transform from substantially planar to concave.

15. The method of claim 12 wherein:
the step of allowing the adhesive to cure causes the second sheet of glass to transform from substantially planar to a three dimensional catenary.

16. The method of claim 12 wherein:
the step of allowing the adhesive to cure causes the cross-section through a central portion of the second sheet of glass to transform from a straight line to a catenary.

17. A method for assembling a first and second sheet of glass comprising the steps of:
applying adhesive tape to a perimeter of the first sheet of glass while leaving a gap where there is no adhesive tape;
placing the second sheet of glass atop the adhesive tape;
calculating the amount (X) of optical adhesive required to hold the first sheet of glass parallel to the second sheet of glass throughout a curing of the optical adhesive;
inserting less than X optical adhesive into the gap;
holding the first sheet of glass such that it remains substantially planar; and
allowing the adhesive to cure.

18. The method of claim 17 wherein:
the step of inserting less than X optical adhesive into the gap is performed by inserting 5%-25% less than X into the gap.

19. A glass assembly for use with an electronic display within a housing, the assembly comprising:
a rear sheet of glass bonded to a front sheet of glass;
a pair of opposing ledges within the housing which sandwich the rear sheet of glass and front sheet of glass; and
an electronic display positioned within the housing and adjacent to the rear sheet of glass;
wherein the rear sheet of glass bows away from the electronic display while the front sheet of glass is substantially planar.

20. The glass assembly of claim 19 wherein:
the electronic display is a liquid crystal display (LCD).
